(19) United States
(12) Patent Application Publication
(10) Pub. No.: US 2025/0300147 A1
(43) Pub. Date: Sep. 25, 2025

(54) OPTICAL WAVEGUIDE FOR CO-PACKAGED OPTICS

(71) Applicant: MELLANOX TECHNOLOGIES, LTD., Yokneam (IL)

(72) Inventors: Barak FREEDMAN, Binyamina (IL); Amit OREN, Ramat Hasharon (IL)

(73) Assignee: MELLANOX TECHNOLOGIES, LTD., Yokneam (IL)

(21) Appl. No.: 18/891,159

(22) Filed: Sep. 20, 2024

Related U.S. Application Data
(60) Provisional application No. 63/569,554, filed on Mar. 25, 2024.

(51) Int. Cl. H01L 25/16; G02B 6/42; H01L 23/00; H01L 23/498

(52) U.S. Cl. CPC H01L 25/167; G02B 6/4228; G02B 6/4269; G02B 6/428; G02B 6/4292; H01L 23/49816; H01L 24/16; H01L 2224/16225; H01L 2924/19011

(57) ABSTRACT

Some embodiments of the present disclosure are directed to an optical waveguide for co-packaged optics packages. For example, a module may include a substrate having a substrate optical waveguide, an interposer disposed on a surface of the substrate, where the interposer comprises an interposer optical waveguide, and where the interposer is configured to optically align the interposer optical waveguide with the substrate optical waveguide, a main die disposed on a surface of the interposer, and a photonic IC disposed on the surface of the interposer and configured to be in optical communication with the interposer optical waveguide. Additionally, or alternatively, the substrate optical waveguide may be configured to convey optical signals between the substrate and the interposer. Further, the interposer optical waveguide may be configured to convey optical signals between the surface of the substrate and the interposer.

### CROSS-REFERENCE TO RELATED APPLICATION

The present application claims the benefit of U.S. patent application Ser. No. 63/569,554 for a “Substrate-Embedded Optical Waveguide for Co-Packaged Optics Package” filed Mar. 25, 2024, which is hereby incorporated by reference in its entirety.

### TECHNOLOGICAL FIELD

The present disclosure relates to an electronic device integrating optical and electrical elements on a single substrate (e.g., a co-packaged optics (CPO) package).

### BACKGROUND

With demand for high-speed and high-volume data communication increasing, communications providers are increasingly adopting optics-based communication solutions. To meet these demands, methods of packaging optical and electrical elements together are being developed.

### GENERAL DESCRIPTION

In one aspect, the present disclosure is directed to a module including a substrate having a substrate optical waveguide, an interposer disposed on a surface of the substrate, where the interposer may include an interposer optical waveguide, and where the interposer may be configured to optically align the interposer optical waveguide with the substrate optical waveguide, a main die at least partially disposed on a surface of the interposer, and at least one photonic integrated circuit (IC) being at least partially disposed on the surface of the interposer and configured to be in optical communication with the interposer optical waveguide. In some embodiments, the substrate optical waveguide may be configured to convey optical signals between the surface of the substrate and the interposer. Further, the interposer optical waveguide may be configured to convey optical signals between the surface of the substrate and the surface of the interposer. Additionally, and/or alternatively, the substrate may have a substrate thickness between the surface of the substrate and another surface of the substrate, and the substrate optical waveguide may be embedded within the substrate thickness.

In some embodiments, the interposer may be electrically connected to the surface of the substrate. Further, the main die may be mechanically and electrically connected to the interposer, and wherein the main die is in electrical communication with the substrate via the interposer. Additionally, and/or alternatively, the photonic IC may be configured to be in optical communication with the interposer optical waveguide.

In some embodiments, the photonic IC may be configured to be in electrical communication with the main die. Further, the module may include a cooling system proximate the main die and the photonic IC, where the cooling system may be configured to remove heat from the main die and the photonic IC. Additionally, and/or alternatively, the module may be deployed in a CPO package.

In another aspect, the present disclosure is directed to a method of manufacturing a module. In some embodiments, the method may include forming a substrate optical waveguide in a substrate, forming an interposer optical waveguide through an interposer, disposing a main die on a surface of the interposer, disposing a photonic integrated circuit (IC) on the surface of the interposer, and disposing the interposer on a surface of the substrate such that the photonic IC is in optical communication with the substrate optical waveguide via the interposer optical waveguide. Further, the method may include performing a ball-grid-array reflow process to mechanically and electrically connect the substrate to a system printed circuit board. Additionally, and/or alternatively, the method may include disposing a cooling system proximate the main die and the photonic IC. In some embodiments, and/or alternatively, the method may include disposing an optical connector on the surface of the substrate such that the optical connector is in optical communication with the photonic IC via the substrate optical waveguide and the interposer optical waveguide.

In another aspect, the present disclosure is directed to a device including a signal transmission region having a top sub-region, one or more photonic integrated circuits (ICs) disposed in the top sub-region, where the one or more photonic ICs may be in optical communication with the top sub-region, and a main die disposed in the top sub-region proximate to and in substantially the same plane as the one or more photonic ICs, where the main die may be in electrical communication with the one or more photonic ICs, and where the signal transmission region may be configured to carry an optical signal to the signal transmission region through the signal transmission region to the top sub-region. In some embodiments, the signal transmission region may include a substrate region having a top substrate region and an interposer region disposed on the top substrate region. Further, the substrate region may include one or more substrate optical waveguides and the interposer region may include one or more interposer optical waveguides. Additionally, and/or alternatively, the interposer region may be configured to optically align the one or more substrate optical waveguides with the one or more interposer optical waveguides.

In some embodiments, the one or more substrate optical waveguides may be configured to convey optical signals. Further, the top substrate region may be configured to be in electrical communication with the interposer region. Additionally, and/or alternatively, the signal transmission region may be disposed on a system printed circuit board (PCB).

In some embodiments, the device may include a cooling system proximate the main die and the one or more photonic ICs, where the cooling system may be configured to remove heat from the main die and the one or more photonic ICs. Further, the device may be deployed in a CPO package.

In another aspect, the present disclosure is directed to a method of manufacturing an electronic device. In some embodiments, the method may include providing a signal transmission region having a top sub-region, disposing one or more photonic ICs in the top sub-region, and disposing a main die in the top sub-region proximate to and in substantially the same plane as the one or more photonic ICs. Further, the method may include providing a substrate region having a top substrate region in the signal transmission region and disposing an interposer region on the top substrate region. Additionally, and/or alternatively, the method may include forming one or more substrate optical waveguides in the substrate region, forming one or more interposer optical waveguides in the interposer region, and optically aligning the one or more substrate optical waveguides with the one or more interposer optical waveguides.

In some embodiments, the method may include performing a ball-grid-array reflow process to mechanically and electrically connect the substrate region to a system printed circuit board. Further, the method may include disposing a cooling system proximate the main die and the one or more photonic ICs.

The features, functions, and advantages that have been discussed may be achieved independently in various embodiments of the present disclosure or may be combined with yet other embodiments, further details of which may be seen with reference to the following description and drawings.

### BRIEF DESCRIPTION OF THE DRAWINGS

Having thus described embodiments of the disclosure in general terms, reference will now be made to the accompanying drawings, wherein:

FIG. 1A schematically depicts a side view of an electronic device;

FIG. 1B schematically depicts a side view of another electronic device;

FIG. 2 is a schematic, partially exploded, perspective view of a CPO device;

FIG. 3 illustrates a module, in accordance with an embodiment of the present disclosure;

FIG. 4 illustrates a device, in accordance with an embodiment of the present disclosure;

FIG. 5 schematically depicts an electronic device, in accordance with an embodiment of the present disclosure;

FIG. 6 is a flowchart illustrating a method of manufacturing a module, in accordance with an embodiment of the present disclosure;

FIG. 7 is a flowchart illustrating a method of manufacturing an electronic device, in accordance with an embodiment of the present disclosure;

FIG. 8 illustrates a block diagram that schematically illustrates a multi-chip module (MCM)-based apparatus, in accordance with an embodiment of the present disclosure;

FIG. 9 illustrates a co-packaged system, in accordance with an embodiment of the present disclosure; and

FIG. 10 illustrates a system, in accordance with an embodiment of the present disclosure.

### DETAILED DESCRIPTION OF EMBODIMENTS

Embodiments of the present disclosure will now be described more fully hereinafter with reference to the accompanying drawings, in which some, but not all, embodiments of the disclosure are shown. Indeed, the disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). Like numbers refer to like elements throughout. No element, act, or instruction used herein should be construed as critical or essential unless explicitly described as such.

As noted, with demand for high-speed and high-volume data communication increasing, communications providers are increasingly adopting optics-based communication solutions. To meet these demands, methods of packaging optical and electrical elements together are being developed (e.g., co-packaged optics (CPO)). An electronic device (e.g., a CPO package) may integrate photonic high-speed optical interconnect components with functional switch application-specific integrated circuits (ASICs) or graphics processing units (GPUs) on a common substrate. By using such electronic devices, computing systems may significantly reduce cost and power consumption over current systems.

Current methods of manufacturing electronic devices involve separate photonic integrated circuits (ICs) and main dies, electric connectivity through substrates, and fibers attached directly to the photonic ICs (e.g., combinations of lasers, optical amplifiers, waveguides, modulators, demodulators, central processing units (CPUs), graphics processing units (GPUs), memory interfaces, intersystem optical interfaces, photodetectors, and/or the like for use in quantum computing, fiber-optic communication, photonic computing, biomedicine, data centers, and/or the like). The current method of manufacturing such electronic devices results in complex and expensive fiber to photonic IC connection methods, multi-chip-module (MCM) assemblies, and thermal solutions. Additionally, current methods require cooling for separate elements, reduced photonic IC cooling area due to connectors, and increased package size to accommodate multiple dies.

In some embodiments, the present disclosure is directed to an electronic device that may include photonic ICs in a main die stack, provide an optical path through the main die stack, and modify the substrate to include waveguides (e.g., buried or on the surface), stack alignment elements, and optical connector alignment elements. One of ordinary skill in the art in view of the present disclosure may understand that such modifications may result in a traditional package assembly, reduced package size, a simplified cooling solution, and a removal of optical connector size dependency on photonic IC size.

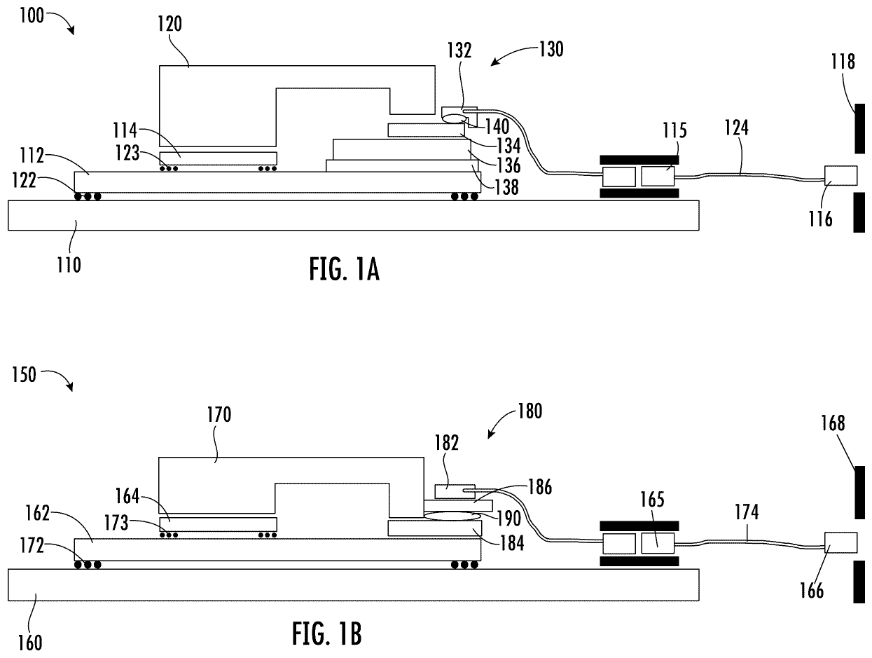

In some embodiments, the electronic device may include an interposer (e.g., an interface that facilitates connections between different elements) with the main die (e.g., a piece of material including circuit components) and the photonic IC disposed on top of the interposer. As will be appreciated by one of ordinary skill in the art in view of the present disclosure, an interposer may include electrical connections and/or optical connections. Further, the electronic device may include a substrate with the interposer disposed on top of the substrate. Such a structure may remedy problems associated with current electronic devices (e.g., electronic devices of FIGS. 1A and 1B) as the photonic ICs may be included in a main die stack proximate the main die.

Embodiments of the present disclosure facilitate this configuration for an electronic device by providing an optical path through the main die stack, and modifying the substrate to include waveguides, buried or on the surface, stack alignment elements, and optical connector alignment elements. In some embodiments, the substrate of the electronic device may include at least one optical waveguide and the interposer of the electronic device may include at least one optical waveguide. Further, the substrate may include a connector (e.g., a multi-fiber push-on (MPO) connector), where an optical signal may be input to the at least one optical waveguide of the substrate. The optical signal may travel through the at least one optical waveguide of the substrate and may be transmitted to the at least one waveguide of the interposer. In some embodiments, the at least one optical waveguide of the substrate and the at least one optical waveguide of the interposer may be optically aligned to one another (e.g., by the inclusion of collimating lenses). The optical signal may travel through the interposer and may be transmitted to the photonic ICs, where the optical signal may be modified before being finally transmitted to the main die. Such modifications may result in a traditional package assembly (reducing package size), a simplified cooling solution, no electrical high-speed traces on the substrate, and a removal of optical connector size dependency on photonic IC size.

As noted, the separation of main dies and photonic ICs necessitates complex and expensive connection methods, MCM assemblies, and thermal solutions. Further, the separation of main dies and photonic ICs results in increased package sizes. As will be appreciated by one of ordinary skill in the art in view of the present disclosure, eliminating this separation, by fabricating a single die stack including the photonic ICs and main dies, may remedy the aforementioned issues. Embodiments of the present disclosure may operate using a single die stack facilitated by the optical connections (e.g., a combination of an interposer, waveguides, and/or collimating lenses) for the die being moved to the package substrate.

In another illustrative embodiment, a semiconductor package may include a substrate, N input ports, an electrical block on the substrate and/or may be configured to route signals in an electrical domain. In some embodiments, the electrical block may include a plurality of electrical switches and each electrical switch may include M input ports. Further, the semiconductor package may include an optical block on the substrate and may be communicatively coupled to the electrical block. Additionally, or alternatively, the optical block may be configured to route signals in an optical domain. In some embodiments, a configuration of the optical block and a configuration of the electrical block are based on at least a number of the N input ports.

FIG. 1A schematically depicts a side view of an electronic device 100. As shown in FIG. 1A, the electronic device 100 may include a system printed circuit board (PCB) 110 (e.g., a device PCB, a product PCB, a switch PCB, and/or the like), a multi-chip module (MCM) substrate 112, a main die 114, a socket 138, a chip-scale optical package (CSOP) 136, a photonic IC 134, a connector 132, a cooling system 120, and mid-board optical adapters 115 (e.g., mid-board MPO adapters and/or the like). As also shown in FIG. 1A, the mid-board optical adapters 115 may be connected to one or more optical connectors 116 (e.g., MPO connectors and/or the like) of a system front panel 118 by one or more optical connector cables 124 (e.g., MPO connector cables and/or the like). As will be appreciated by one of ordinary skill in the art in view of the present disclosure, the electronic device 100 may be similar to and/or representative of a conventional design for an electronic device.

The MCM substrate 112, the main die 114, the socket 138, the CSOP 136, the photonic IC 134, and the connector 132 may form an electronic module 730 similar to the electronic module 100 as shown and described herein with respect to FIG. 1. As shown in FIG. 1A, the MCM substrate 112 may be mechanically and/or electrically connected to the system PCB 110 by a ball grid array (BGA) (e.g., surface mount packaging using an array of solder balls) 122 (e.g., after a BGA reflow process and/or the like). As also shown in FIG. 1A, the main die 114 may be mechanically and/or electrically connected to the MCM substrate 112 via a flip-chip and reflow process 123. The photonic IC 134 and the CSOP 136 may be mechanically and/or electrically connected to the MCM substrate 112 by the socket 138.

The connector 132 may be mechanically secured to the photonic IC 134 using adhesive 140 and may include one or more optical connector cables 124 to the photonic IC 134 such that the photonic IC 134 is in optical communication with the mid-board optical adapters 115. Assembling the MCM module 730 (e.g., the MCM substrate 112, the main die 114, the socket 138, the CSOP 136, the photonic IC 134, and the connector 132) may include actively aligning the connector 132 with the photonic IC 134. In this regard, the assembly method may include applying an adhesive 140 to a surface of the photonic IC 134 and/or a surface of the connector 132. The assembly method may further include actively aligning the connector 132 with an optical window of the photonic IC 134 while transmitting optical signals through the connector 132 and testing the optical signals. The assembly method may include actively changing the position of the connector 132 on the photonic IC 134 to determine an optimal alignment of the connector 132 with respect to the photonic IC 134 that ensures complete and/or near-complete transmission of the optical signals through the connector 132. The assembly method may include, upon determining an optimal alignment, curing the adhesive 140 to permanently adhere the connector 132 to the photonic IC 134.

As shown in FIG. 1A, the cooling system 120 is proximate the main die 114 and the photonic IC 134. However, due to the separated positioning of the main die 114 and the photonic IC 134, the configuration of the cooling system 120 must be complex, and the positioning of the connector 132 prevents cooling of a portion of the photonic IC 134. Furthermore, the overall package size is large due to the separated positioning of the main die 114 and the photonic IC 134, the height of the socket 138, CSOP 136, and connectors 132 on the photonic IC 134, and the height of the complexly configured cooling system 120. As will be appreciated by one of ordinary skill in the art in view of the present disclosure, the aforementioned problems associated with embodiments of FIG. 1A are the result of the two separated die stacks.

FIG. 1B schematically depicts a side view of another electronic device 150. As shown in FIG. 1B, the electronic device 150 may include a system printed circuit board (PCB) 160 (e.g., a device PCB, a product PCB, a switch PCB, and/or the like), a multi-chip module (MCM) substrate 162, a main die 164, a photonic IC 184, a receptacle 186, a connector 182, a cooling system 170, and mid-board optical adapters 165 (e.g., mid-board MPO adapters and/or the like). As also shown in FIG. 1B, the mid-board optical adapters 165 may be connected to one or more optical connectors 166 (e.g., MPO connectors and/or the like) of a system front panel 168 by one or more optical connector cables 174 (e.g., MPO connector cables and/or the like). As will be appreciated by one of ordinary skill in the art in view of the present disclosure, the electronic device 150 may be similar to and/or representative of a conventional design for an electronic device.

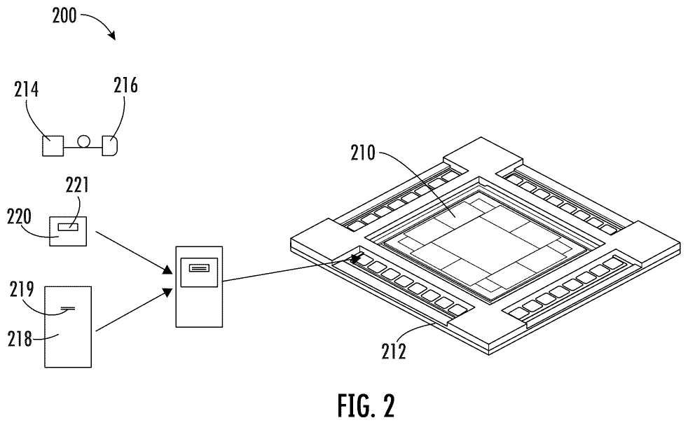

The MCM substrate 162, the main die 164, the photonic IC 184, the receptacle 186, and the connector 182 may form an electronic module 180 similar to the CPO device 200 as shown and described herein with respect to FIG. 2. As shown in FIG. 1B, the MCM substrate 162 may be mechanically and/or electrically connected to the system PCB 160 by a ball grid array (BGA) 172 (e.g., after a BGA reflow process and/or the like). As also shown in FIG. 1B, the main die 164 may be mechanically and/or electrically connected to the MCM substrate 162 via a flip-chip and reflow process 173. The photonic IC 184 may also be mechanically and/or electrically connected to the MCM substrate 162.

As shown in FIG. 1B, the receptacle 186 may be secured to the photonic IC 184 using an adhesive 190 and may detachably connect the connector 182 and one or more optical connector cables 174 to the photonic IC 184 such that the photonic IC 184 is in optical communication with the mid-board optical adapters 165. Assembling the electronic module 180 (e.g., the MCM substrate 162, the main die 164, photonic IC 184, the receptacle 186, and the connector 182) may include actively aligning the receptacle 186 with the photonic IC 184. In this regard, the assembly method may include applying an adhesive 190 to a surface of the photonic IC 184 and/or a surface of the receptacle 186 and connecting a golden connector (e.g., a test connector) to the receptacle 186. The assembly method may further include actively aligning the optical path window of the receptacle 186 with an optical window of the photonic IC 184 while transmitting optical signals through the golden connector and the receptacle 186 and testing the optical signals. The assembly method may include actively changing the position of the receptacle 186 on the photonic IC 184 to determine an optimal alignment of the receptacle 186 with respect to the photonic IC 184 that ensures complete and/or near-complete transmission of the optical signals through the golden connector and the receptacle 186. The assembly method may include, upon determining an optimal alignment, curing the adhesive 190 to permanently adhere the receptacle 186 to the photonic IC 184.

As shown in FIG. 1B, the cooling system 170 is proximate the main die 164 and the photonic IC 184. However, due to the separated positioning of the main die 164 and the photonic IC 184, the configuration of the cooling system 170 must be complex, and the positioning of the receptacle 186 and the connector 182 prevents cooling of a portion of the photonic IC 184. Furthermore, the overall package size is large due to the separated positioning of the main die 164 and the photonic IC 184, the height of the receptacle 186 and connector 182 on the photonic IC 184, and the height of the complexly configured cooling system 170. As will be appreciated by one of ordinary skill in the art in view of the present disclosure, the aforementioned problems associated with embodiments of FIG. 1B are the result of the two separated die stacks.

FIG. 2 is a schematic, partially exploded, perspective view of a CPO device 200. As shown in FIG. 2, the CPO device 200 may include a substrate 212, a chip-on-wafer 210 (e.g., a main die), and a plurality of photonic dies 218 (e.g., photonic ICs). As also shown in FIG. 2, the chip-on-wafer 210 may be positioned on a central portion of the substrate 212, and the plurality of photonic dies 218 may be positioned on a peripheral portion of the substrate 212. As will be appreciated by those of ordinary skill in the art in view of this disclosure, a representative photonic die 218 is depicted on the left side of FIG. 2 as being representative of the photonic dies 218 on the peripheral portion of the substrate 212.

As shown in FIG. 2, a receptacle 220 including an optical path window 221 may be positioned on each of the photonic dies 218, and each receptacle 220 may be configured to align its optical path window 221 and a corresponding detachable connector 214 with an optical path window 221 of a corresponding photonic die 218. The detachable connectors 214 may be connected via optical fibers to an optical connector 216 (e.g., an MPO connector and/or the like), which are in optical communication with one or more optical devices (not pictured). In this way, the receptacles 220 and the detachable connectors 214 optically connect the photonic dies 218 of the CPO device 200 to one or more optical devices.

In some embodiments, one or more of the photonic dies 218 may be configured to receive electrical signals from the chip-on-wafer 210 (e.g., via electrical traces through the substrate 212), convert the electrical signals to optical signals, and transmit the optical signals to one or more optical devices. Additionally, or alternatively, one or more of the photonic dies 218 may be configured to receive optical signals from one or more optical devices, convert the optical signals to electrical signals, and transmit the electrical signals to the chip-on-wafer 210 (e.g., via electrical traces through the substrate 212).

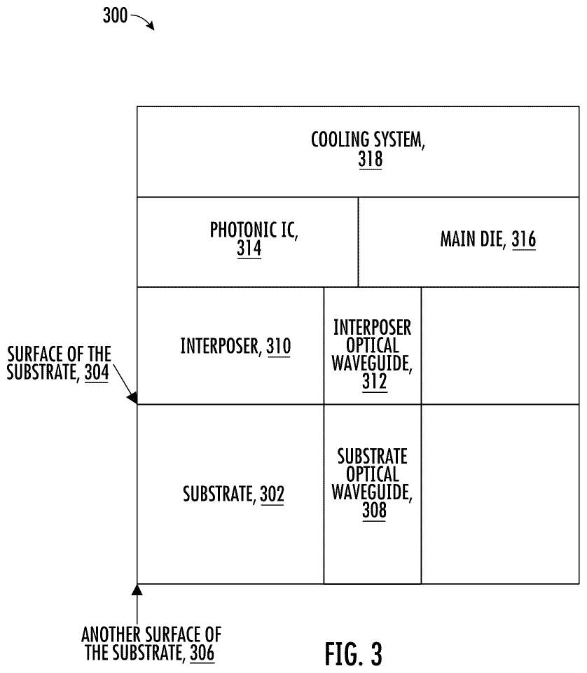

FIG. 3 illustrates a module 300, in accordance with an embodiment of the present disclosure. In some embodiments, the module 300 may include a substrate 302 having a surface of the substrate 304 and another surface of the substrate 306 opposite the surface of the substrate 304, where the substrate 302 includes a substrate optical waveguide 308. Further, an interposer 310 may be disposed on the surface of the substrate 304, where the interposer 310 may include an interposer optical waveguide 312. Additionally, or alternatively, the interposer 310 may be configured to optically align the interposer optical waveguide 312 with the substrate optical waveguide 308.

In some embodiments, a main die 316 may be disposed on a surface of the interposer 310 and a photonic IC 314 may be disposed on the surface of the interposer 310 and in substantially the same plane as the main die 316 and may be configured to be in optical communication with the interposer optical waveguide 312. In some embodiments, the main die 316 may be adjacent to the photonic IC 314. Further, the substrate optical waveguide 308 may be configured to convey optical signals between the surface of the substrate 304 and the interposer 310. Additionally, or alternatively, the interposer optical waveguide 312 may be configured to convey optical signals between the surface of the substrate 304 and the surface of the interposer 310.

In some embodiments, the substrate 302 may have a substrate thickness between the surface of the substrate 304 and the other surface of the substrate 306, and the substrate optical waveguide 308 may be within the substrate thickness. Further, the interposer 310 may be electrically connected to the surface of the substrate 304. Additionally, or alternatively, the main die 316 may be mechanically and electrically connected to the interposer 310, and the main die 316 may be in electrical communication with the substrate 302 via the interposer 310.

In some embodiments, photonic IC 314 may be configured to be in optical communication the interposer optical waveguide 312. Further, the photonic IC 314 may be configured to be in electrical communication with the main die 316. Additionally, or alternatively, the module 300 may include a cooling system 318 proximate the main die 316 and the photonic IC 314, where the cooling system 318 may be configured to remove heat from the main die 316 and the photonic IC 314.

As will be appreciated by one of ordinary skill in the art in view of the present disclosure, the module 300 may include additional embodiments, such as any single embodiment or any combination of embodiments described herein.

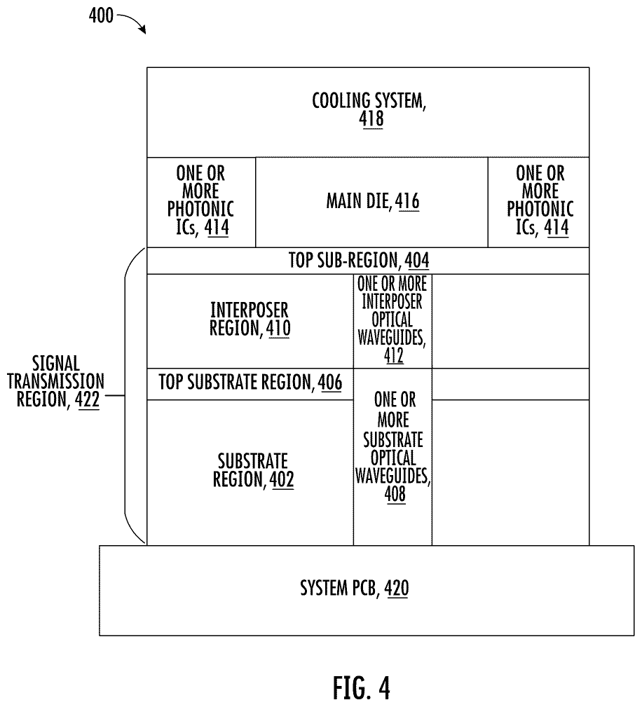

FIG. 4 illustrates a device 400, in accordance with an embodiment of the disclosure. In some embodiments, the device 400 may include a signal transmission region 422 having a top sub-region 404, one or more photonic ICs 414 disposed in the top sub-region 404, where the one or more photonic ICs 414 may be in optical communication with the top sub-region 404, and a main die 416 disposed in the top sub-region 404 proximate to and in substantially the same plane as the one or more photonic ICs 414, where the main die 416 may be in electrical communication with the one or more photonic ICs 414. Further, the signal transmission region 422 may be configured to carry an optical signal to the signal transmission region 422 through the signal transmission region 422 to the top sub-region 404.

In some embodiments, the signal transmission region 422 may include a substrate region 402 having a top substrate region 406 and an interposer region 410 disposed on the top substrate region 406. Further, the substrate region 402 may include one or more substrate optical waveguides 408, and the interposer region 410 may include one or more interposer optical waveguides 412. Additionally, or alternatively, the interposer region 410 may be configured to optically align the one or more substrate optical waveguides 408 with the one or more interposer optical waveguides 412.

In some embodiments, the one or more substrate optical waveguides 408 may be configured to convey optical signals. Further, the top substrate region 406 may be configured to be in electrical communication with the interposer region 410. Additionally, or alternatively, the signal transmission region 422 may be disposed on a system printed circuit board (PCB) 420. In some embodiments, the device 400 may include a cooling system 418 proximate the main die 416 and the one or more photonic ICs 414, where the cooling system 418 may be configured to remove heat from the main die 416 and the one or more photonic ICs 414.

As will be appreciated by one of ordinary skill in the art in view of the present disclosure, the device 400 may include additional embodiments, such as any single embodiment or any combination of embodiments described herein.

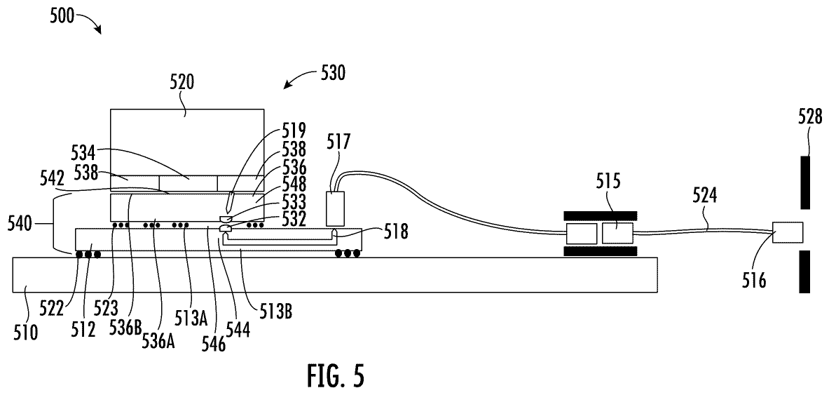

Some embodiments of the present disclosure are directed to a module (e.g., a co-packaged optics (CPO) package), an electronic module, an electronic device, a method of manufacturing an module, a method of manufacturing an electronic module, a method of manufacturing an electronic device, and/or the like in which a photonic IC is in optical communication with a connector via optical waveguides and lenses of an interposer and a substrate. For example, FIG. 5 schematically depicts an electronic device 500, in accordance with an embodiment of the present disclosure.

As shown in FIG. 5, the electronic device 500 may include a system printed circuit board (PCB) 510 (e.g., a device PCB, a product PCB, a switch PCB, and/or the like), a substrate 512, a main die 534, an interposer 536 (e.g., an interposer, a silicon interposer, and/or the like), a pair of photonic ICs 538, an optical connector 517 (e.g., an MPO connector and/or the like), a cooling system 520 (e.g., for removing heat and/or cooling the main die 534 and the photonic ICs 538), and mid-board optical adapters 515 (e.g., mid-board MPO adapters and/or the like). As also shown in FIG. 5, the optical connector 517 and/or the mid-board optical adapters 515 may be connected to one or more optical connectors 516 (e.g., MPO connectors and/or the like) of a system front panel 528 by one or more optical connector cables 524 (e.g., MPO connector cables and/or the like).

The substrate 512, the main die 534, photonic ICs 538, the interposer 536, and the optical connector 517 may form a module 530 (e.g., a CPO package), which in some respects may be similar to the CPO device 200 as shown and described herein with respect to FIG. 2. As shown in FIG. 5, the substrate 512 may be mechanically and/or electrically connected to the system PCB by a ball grid array (BGA) 522 (e.g., after a BGA reflow process and/or the like).

As shown in FIG. 5, the substrate 512 may have a first substrate surface 513a and a second substrate surface 513b opposite the first substrate surface 513a, where the substrate 512 has a substrate thickness between the first substrate surface 513a and the second substrate surface 513b. The substrate 512 may include one or more substrate collimating lenses 532 positioned on the first substrate surface 513a, as shown in FIG. 5. The substrate 512 may also include one or more substrate optical waveguides 518 within the thickness of the substrate 512, where each substrate waveguide of the one or more substrate optical waveguides 518 is configured to convey optical signals through the substrate 512 between the optical connector 517 and a respective substrate collimating lens 532 of the one or more substrate collimating lenses 532, or vice versa, as shown in FIG. 5.

The interposer 536 may be disposed on the first substrate surface 513a, as shown in FIG. 5, and may have a first interposer surface 536b and a second interposer surface 536a opposite the first interposer surface 536b. As shown in FIG. 5, the second interposer surface 536a may be electrically connected 823 to the first substrate surface 513a. The interposer 536 may have an interposer thickness between the first interposer surface 536b and the second interposer surface 536a. As shown in FIG. 5, the interposer 536 may include one or more interposer collimating lenses 533 on the second interposer surface 536a. The interposer 536 may also include one or more interposer optical waveguides 519 (e.g., through-silicon vias (TSVs)) within the interposer 536, as shown in FIG. 5, where each interposer optical waveguide 519 of the one or more interposer optical waveguides 519 is configured to convey optical signals between the first interposer surface 536b and a respective interposer collimating lens 533 of the one or more interposer collimating lenses 533.

As shown in FIG. 5, the main die 534 may be mechanically and/or electrically connected to the first connector surface 536b. In some embodiments, the main die 534 may be in electrical communication with the substrate 512 via the interposer 536.

As also shown in FIG. 5, the photonic ICs 538 may be disposed on the first connector surface 536b (e.g., proximate the main die 534). The silicon photonic chips 538 may be configured to be in electrical communication with the main die 534 (e.g., via traces through the interposer 536 and/or the substrate 512). In some embodiments, each of the photonic ICs 538 may be configured to be in optical communication with a respective connector optical waveguide 519 of the one or more interposer optical waveguides 519.

The photonic ICs 538 may be in optical communication with the one or more substrate optical waveguides 518 via the one or more interposer optical waveguides 519, the one or more interposer collimating lenses 533, and the one or more substrate collimating lenses 532. Furthermore, the optical connector 516 may be in optical communication with the photonic ICs 538 via the one or more substrate optical waveguides 518, the one or more interposer optical waveguides 519, the one or more interposer collimating lenses 533, and the one or more substrate collimating lenses 532.

In this way, the module 530 may provide an optical path through the three-dimensional stack, rather than via receptacles, connectors, and optical fibers mounted on surfaces of the photonic ICs. Such an optical path generally corresponds to conventional designs for routing electrical paths through a module and/or a device, such that assembly methods traditionally used to establish electrical paths may also be used to establish optical paths through a module and/or a device. Additionally, such an optical path may eliminate the requirement to perform active alignment during assembly.

Furthermore, because the interposer collimating lenses 533 and the substrate collimating lenses 532 use an extended-beam technique to convey optical signals across the optical interface from the interposer 536 to the substrate 512 and vice versa, the optical interface is not sensitive to lateral misalignments of the interposer 536 with respect to the substrate 512, which reduces the likelihood that assembly inaccuracies will inhibit the performance of the module 530. Although such an extended-beam technique may be sensitive to angular misalignments, the physical interface between the flat surfaces of the interposer 536 and the substrate 512 significantly reduces the likelihood of angular misalignments.

By using an extended-beam technique to convey optical signals across the optical interface from the interposer 536 to the substrate 512 and vice versa, the module 530 design provides a robust solution using traditional assembly methods without a top-mounted connector, a receptacle, and/or the like. Furthermore, such a module 530 design reduces overall package size, reduces the size of the cooling system 520 due to the proximity of the main die 534 and the photonic ICs 538, and permits the use of larger optical connector 517 (e.g., MPO connectors) on the package, rather than specialized connectors for the silicon photonic chips. Moreover, such a module 530 design permits moving the optical connector 517 to the substrate 512, which simplifies assembly. Additionally, by positioning a photonic IC 538 on top of a Chip on Wafer on Substrate (CoWoS), the module 530 design does not require a separate CSOP package, a socket, high-speed traces on the substrate, and/or the like.

As also shown in FIG. 5, the electronic device 500 may include a signal transmission region 540. In some embodiments, the signal transmission region 540 may include a top sub-region 542, a substrate region 544 having a top substrate region 546, and an interposer region 548. Further, the interposer region 548 may be disposed on the top substrate region 546 of the substrate region 544. Additionally, or alternatively, a main die 534 and one or more silicon photonic chips 538 may be disposed on the top sub-region 542 of the signal transmission region 540. In some embodiments, the main die 534 may be disposed in substantially the same plane as the one or more photonic ICs 538. Additionally, or alternatively, the substrate region 544 of the signal transmission region 540 may be disposed on a PCB 510.

In some embodiments, the main die 534 is in electrical communication with the one or more photonic ICs 538. Further, the signal transmission region 540 may be configured to transmit optical signals to the one or more photonic ICs 538 via the top sub-region 542. Additionally, or alternatively, the signal transmission region 540 may include one or more substrate optical waveguides 518 in the substrate region 544 and/or one or more interposer optical waveguides 519 in the interposer region 548. In some embodiments, the one or more substrate optical waveguides 518 and/or the one or more interposer optical waveguides 519 may be configured to convey an optical signal to the top sub-region 542 of the signal transmission region 540. In some embodiments, the electronic device 500 may include a cooling system 520 proximate the main die 534 and/or the one or more photonic ICs, 538, where the cooling system 520 may be configured to remove heat from the main die 534 and/or the one or more silicon photonic chips 538. As will be appreciated by one of ordinary skill in the art in view of the present disclosure, embodiments of the present disclosure enable a single die stack, thus embodiments of the present disclosure enjoy a smaller package size and a less complex cooling system.

As will be appreciated by one of ordinary skill in the art in view of the present disclosure, the electronic device may include additional embodiments, such as any single embodiment or any combination of embodiments described herein.

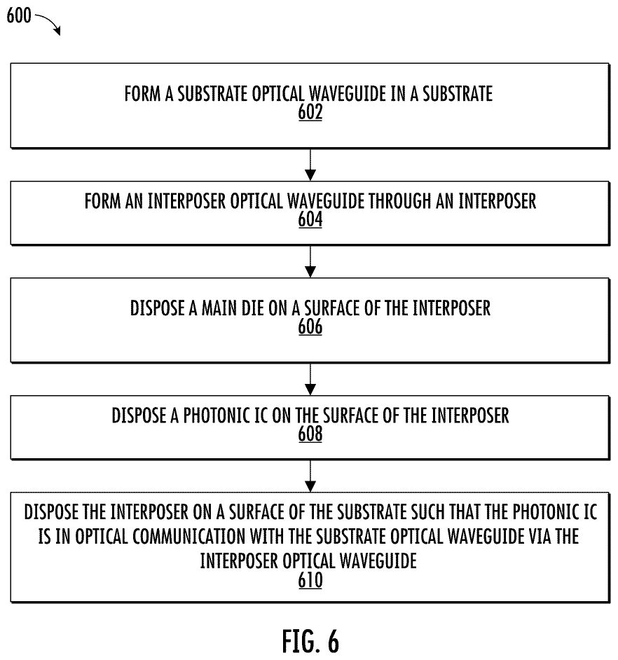

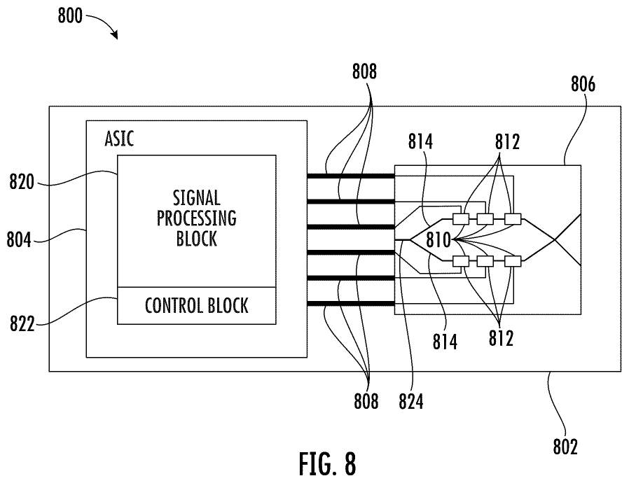

FIG. 6 is a flowchart illustrating a method 600 of manufacturing a module, in accordance with an embodiment of the disclosure. In some embodiments, the method 600 may be used to manufacture a module and/or an electronic device similar to the module and the electronic device as shown and described herein with respect to FIG. 8.

As shown in block 602, the method 600 may include forming a substrate optical waveguide in a substrate (e.g., the substrate 513 with the one or more substrate optical waveguides 518 shown and described herein with respect to FIG. 5). In some embodiments, the substrate may have a substrate width between a surface of the substrate and another surface of the substrate. Further, the substrate width may be constant and/or the substrate width may be variable.

In some embodiments, the substrate optical waveguide may be formed on the surface of the substrate, the other surface of the substrate, and/or in between the surface of the substrate and the other surface of the substrate in the substrate width. Further, a width of the substrate optical waveguide may be constant and/or the width of the substrate optical waveguide may be variable. Additionally, or alternatively, a depth of the substrate optical waveguide may be constant and/or the depth of the substrate optical waveguide may be variable. In some embodiments, the substrate optical waveguide and/or the substrate may be similar to the substrate optical waveguides and/or the substrate as shown and described herein with respect to FIG. 3.

As shown in block 604, the method 600 may include forming an interposer optical waveguide through an interposer (e.g., the interposer 536 with the one or more interposer optical waveguides 519 shown and described herein with respect to FIG. 5). In some embodiments, a width of the interposer optical waveguide may be constant and/or the width of the interposer optical waveguide may be variable. Additionally, or alternatively, a depth of the interposer optical waveguide may be constant and/or the depth of the interposer optical waveguide may be variable.

In some embodiments, the interposer optical waveguide may be in optical communication with the substrate optical waveguide. In such an embodiment, an optical signal may be first input into the substrate optical waveguide, travel through the substrate optical waveguide, and/or be transmitted from the substrate optical waveguide to the interposer optical waveguide. Additionally, or alternatively, the surface of the substrate may include one or collimating lenses along the optical path and/or the interposer may include one or more collimating lenses along the optical path (e.g., a one or more substrate collimating lens 532 and/or a one or more connector collimating lens 533 shown and described herein with respect to FIG. 5) to focus the optical signal during transmission between the substrate optical waveguide and the interposer optical waveguide. As will be appreciated by one of ordinary skill in the art in view of the present disclosure, the one or more collimating lenses on the first substrate surface and/or the interposer allow the electronic module to use an extended-beam technique so as to prevent lateral misalignments of the interposer to the substrate. In some embodiments, the interposer optical waveguide and/or the interposer may be similar to the interposer optical waveguides and/or the interposer as shown and described herein with respect to FIG. 5.

As shown in block 606, the method 600 may include disposing a main die on a surface of the interposer (e.g., the main die 534 shown and described herein with respect to FIG. 5). In some embodiments, the main die may be disposed on a portion of the surface of the interposer. Additionally, or alternatively, a plurality of main dies may be disposed on the surface of the interposer. In some embodiments, the main die may be mechanically and/or electrically connected to the interposer. In some embodiments, the main die may be in electrical communication with the substrate via the interposer.

As shown in block 608, the method 600 may include disposing a photonic IC on the surface of the interposer (e.g., the photonic ICs 538 shown and described herein with respect to FIG. 5). In some embodiments, a photonic IC may be disposed on a portion of the surface of the interposer. Further, the photonic IC may be disposed proximate, in substantially the same plane, to the main die. Additionally, or alternatively, a plurality of photonic ICs may be disposed on the surface of the electro-optic coupler. In some embodiments, the photonic IC may be in electrical communication with the main die (e.g., via traces through the interposer and/or the substrate). Further, each of the photonic ICs may be configured to be in optical communication with a respective connector optical waveguide.

As shown in block 610, the method 600 may include disposing the interposer on the surface of the substrate such that the photonic IC is in optical communication with the substrate optical waveguide via the interposer optical waveguide. For example, an optical signal may be first input into the substrate optical waveguide and may travel through the substrate optical waveguide. Further, the optical signal may be transmitted from the substrate optical waveguide, via additional optical elements (e.g., collimating lenses), to the interposer optical waveguide. The optical signal may then travel through the interposer via the interposer optical waveguide before being transmitted to the photonic IC. Additionally, or alternatively, the method 600 may include performing a flip-chip and reflow process to mechanically and/or electrically connect the interposer to the first substrate surface.

In some embodiments, the method 600 may include performing a ball-grid-array reflow process to mechanically and electrically connect the substrate to a system printed circuit board. Additionally, or alternatively, the method 600 may include disposing a cooling system proximate the main die and the one or more photonic ICs. In some embodiments, the method 600 may include disposing one or more optical connectors on the surface of the substrate such that the one or more optical connectors are in optical communication with the one or more photonic ICs via the one or more substrate optical waveguides, the one or more interposer optical waveguides, one or more connector collimating lenses, and one or more substrate collimating lenses.

Method 600 may include additional embodiments, such as any single embodiment or any combination of embodiments described herein. Although FIG. 6 shows example blocks of method 600, in some embodiments, method 600 may include additional blocks, fewer blocks, different blocks, or differently arranged blocks than those depicted in FIG. 6. Additionally, or alternatively, two or more of the blocks of method 600 may be performed in parallel.

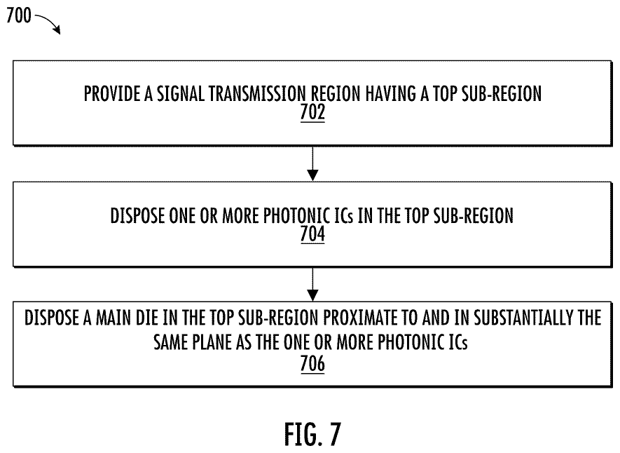

FIG. 7 is a flowchart illustrating a method 700 of manufacturing an electronic device, in accordance with an embodiment of the disclosure. In some embodiments, the method 700 may be used to manufacture a module and/or an electronic device similar to the module and the electronic device as shown and described herein with respect to FIG. 5.

As shown in block 702, the method 700 may include providing a signal transmission region having a top sub-region. In some embodiments a signal transmission region may include a substrate region and/or an interposer region (e.g., similar to the substrate 512 and/or the interposer 536 shown and described herein with respect to FIG. 5). Further, the substrate region may include one or more substrate optical waveguides and/or the interposer region may include one or more interposer optical waveguides (e.g., similar to the one or more substrate optical waveguides 518 and/or the one or more interposer optical waveguides 519 shown and described herein with respect to FIG. 5). Additionally, or alternatively, the interposer region may be disposed on a top region of the substrate region. In some embodiments, the signal transmission region may be configured to carry signals (e.g., electric signals, optical signals, and/or the like) between elements of an electronic device.

As shown in block 704, the method 700 may include disposing one or more photonic ICs (e.g., similar to the photonic ICs 538 shown and described herein with respect to FIG. 5) in the top sub-region. In some embodiments, the one or more photonic ICs may be disposed in the top sub-region such that the one or more photonic ICs are in optical communication with the top sub-region such that an optical signal may be conveyed through the signal transmission region to the top sub-region and transmitted to the one or more photonic ICs.

As shown in block 706, the method 700 may include disposing a main die (e.g., the main die 534 shown and described herein with respect to FIG. 5) in the top sub-region proximate to and in substantially the same plane as the one or more photonic ICs. In some embodiments, the main die may be in electronic communication with the one of more photonic ICs such that an optical signal traveling through the photonic IC may be converted to an electronic signal and transmitted, electronically, to the main die. Further, the main die may be mechanically and/or electrically connected to the interposer region. In some embodiments, the main die may be in electrical communication with the substrate region via the interposer region. Additionally, or alternatively, the method 700 may include performing a flip-chip and reflow process to mechanically and electrically connect the main die to the interposer region.

In some embodiments, the method 700 may include performing a ball-grid-array reflow process to mechanically and electrically connect the substrate region to a system printed circuit board. Additionally, or alternatively, the method 700 may include disposing a cooling system proximate the main die and the one or more photonic ICs. In some embodiments, the method 700 may include disposing one or more optical connectors on the top substrate region such that the one or more optical connectors are in optical communication with the one or more photonic ICs via the one or more substrate optical waveguides, the one or more interposer optical waveguides, one or more connector collimating lenses, and one or more substrate collimating lenses.

Method 700 may include additional embodiments, such as any single embodiment or any combination of embodiments described herein. Although FIG. 7 shows example blocks of method 700, in some embodiments, method 700 may include additional blocks, fewer blocks, different blocks, or differently arranged blocks than those depicted in FIG. 7. Additionally, or alternatively, two or more of the blocks of method 700 may be performed in parallel.

FIG. 8 illustrates a block diagram that schematically illustrates a multi-chip module (MCM)-based apparatus 800, in accordance with an embodiment of the present disclosure. The disclosed embodiments exemplify applications in an MCM that may reduce the number of optical I/Os. In some embodiments, the MCM-based apparatus 800 may include a carrier 802 (e.g., a substrate) supporting an ASIC 804, a photonic chip 806, and/or a number of M short electrical lanes 808 (e.g., M=6 in FIG. 8) having at their ends respective driving electrodes 810 that may conduct driving electrical signals from ASIC 804 to M respective photonic modulator-segments 812, that may convert the M respective driving electrical signals into a single high-order modulated optical signal. In some embodiments, the MCM-based apparatus may include an optical input 824. Further, the ASIC 804 may include a signal processing block 820 and/or a signal control block 822 configured to process and control electrical driving signals. Additionally, or alternatively, the M respective photonic modulator-segments 812 may include optical waveguide arms 814.

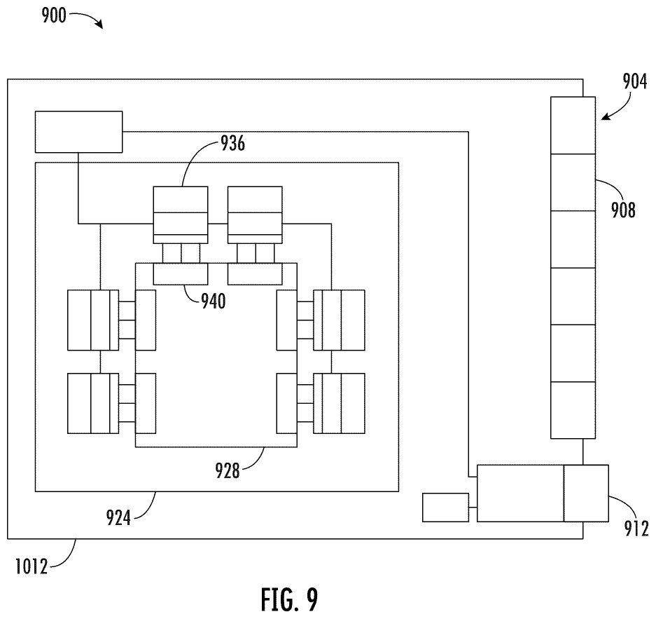

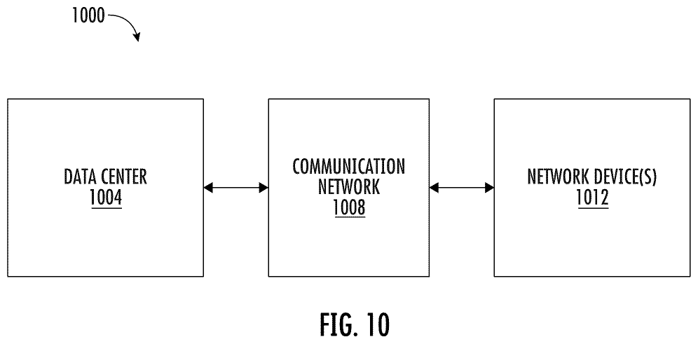

FIG. 9 illustrates a co-packaged system 900, in accordance with an embodiment of the present disclosure. Co-packaging may refer to the close integration of different electrical and/or optoclectronic chips in the same package. In some embodiments, the different chips that constitute the co-packaged system 900 may be assembled on a single substrate in what is typically called a multi-chip module (MCM) assembly 924. Further, the MCM assembly 924 may include switching circuitry 928 surrounded by peripheral chips, which may also be referred to as satellite chips or chiplets 936. In some embodiments, the switching circuitry 928 and chiplets 936 may all be mounted on a common substrate, although such a configuration may not be required. Further, the MCM assembly 924 may be provided in a larger housing of a networking device (e.g., similar to the network device(s) 1012 as shown and described herein with respect to FIG. 10), positioned behind the front panel 904 and transceiver ports 908, 912 exposed at the front panel 904. Additionally, or alternatively, the switching circuitry 928 may include one or more core digital Application Specific Integrated Circuits (ASICs), CPUs, GPUs, microprocessors, FPGAs, combinations thereof, and the like.

In the context of high-throughput DCN switches and optoelectronics, co-packaging may allow transferring the optoelectronic transceivers 940 from the front panel 904 (where they are currently deployed in the form of pluggable modules) to the MCM chiplets 936 inside the enclosure of the networking device(s) 1012. In some embodiments, the fiber optical I/Os from the chiplets 936 may be transferred to the front panel 904 where compact optical connectors now reside, replacing the bulky pluggable ports. This saves front panel 904 area which can be used to accommodate integration of one or more other systems.

FIG. 10 illustrates a system 1000, in accordance with an embodiment of the present disclosure. The system 1000 may include a datacenter 1004, a communication network 1008, and/or one or more network devices 1012. In some embodiments, the datacenter 1004 may correspond to a collection of network devices, such as network switches (e.g., Ethernet switches) connected with a collection of servers and/or computer nodes. The datacenter 1004 may adhere to a networking topology (e.g., a hierarchal networking topology), such as a fat tree topology, a Slim Fly topology, a Dragonfly topology, and/or the like. Additionally, or alternatively, the datacenter 1004 may route traffic amongst the network switches and servers therein, and at least one layer of the topology in the datacenter 1004 is coupled to the communication network 1008 to allow networking traffic to flow between the datacenter 1004 and the network device(s) 1012. As described in more detail below, one or more layers of the topology may include one or more optical switches.

Examples of the communication network 1008 that may be used to connect the datacenter 1004 and the network device(s) 1012 include an Internet Protocol (IP) network, an Ethernet network, an InfiniBand (TB) network, a Fiber Channel network, the Internet, a cellular communication network, a wireless communication network, combinations thereof (e.g., Fiber Channel over Ethernet), variants thereof, and/or the like.

In some embodiments, the one or more network devices 1012 may include one or more of Personal Computer (PC), a laptop, a tablet, a smartphone, a server, a collection of servers, and/or any suitable computing device for sending and receiving signals over the communication network 1008. Additionally, or alternatively, the one or more network devices 1012 correspond to another datacenter, similar to or the same as datacenter 1004.

As noted above, the datacenter 1004 and/or the network device(s) 1012 may include storage devices and/or processing circuitry for carrying out computing tasks, for example, tasks associated with controlling the flow of data internally and/or over the communication network 1008. In some embodiments, such processing circuitry may include software, hardware, or a combination thereof. For example, the processing circuitry may include a memory including executable instructions and a processor (e.g., a microprocessor) that executes the instructions on the memory. Further, the memory may correspond to any suitable type of memory device or collection of memory devices configured to store instructions. Additionally, or alternatively, non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally, or alternatively, the processing circuitry may comprise hardware, such as an application specific integrated circuit (ASIC). Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. In some embodiments, some or all of the processing circuitries may be provided on a Printed Circuit Board (PCB) or collection of PCBs. It should be appreciated that any appropriate type of electrical component or collection of electrical components may be suitable for inclusion in the processing circuitry.

In some embodiments, although not explicitly shown, it should be appreciated that the datacenter 1004 and network device(s) 1012 may include one or more communication interfaces for facilitating wired and/or wireless communication between one another and other unillustrated elements of the system 1000.

In view of the above, it should be appreciated that example embodiments provide optical switches, which may be co-packaged into a single device, and may be used in a suitable datacenter topology to provide improved bandwidth, reduced latency, and/or reduced power consumption.

As will be appreciated by one of ordinary skill in the art in view of this disclosure, the present disclosure may include and/or be embodied as an apparatus (including, for example, a system, a machine, a device, and/or the like), as a method (including, for example, a manufacturing method, a robot-implemented process, and/or the like), or as any combination of the foregoing.

Although many embodiments of the present disclosure have just been described above, the present disclosure may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present disclosure described and/or contemplated herein may be included in any of the other embodiments of the present disclosure described and/or contemplated herein, and/or vice versa.

While certain exemplary embodiments have been described and shown in the accompanying drawings, it is to be understood that such embodiments are merely illustrative of and not restrictive on the broad disclosure, and that this disclosure is not limited to the specific constructions and arrangements shown and described, since various other changes, combinations, omissions, modifications, and substitutions, in addition to those set forth in the above paragraphs, are possible. Those skilled in the art will appreciate that various adaptations, modifications, and combinations of the just described embodiments may be configured without departing from the scope and spirit of the disclosure. For example, devices, modules, components, and/or elements shown in the figures are not necessarily drawn to scale and may vary from that shown without departing from the scope and spirit of the disclosure. Therefore, it is to be understood that, within the scope of the appended claims, the disclosure may be practiced other than as specifically described herein.

What is claimed is:

1. A module, comprising:
a substrate having a substrate optical waveguide;
an interposer disposed on a surface of the substrate, wherein the interposer comprises an interposer optical waveguide, and wherein the interposer is configured to optically align the interposer optical waveguide with the substrate optical waveguide;
a main die at least partially disposed on a surface of the interposer; and
at least one photonic integrated circuit (IC) being at least partially disposed on the surface of the interposer and configured to be in optical communication with the interposer optical waveguide.

2. The module of claim 1, wherein the substrate optical waveguide is configured to convey optical signals between the surface of the substrate and the interposer.

3. The module of any of claim 1, wherein the interposer optical waveguide is configured to convey optical signals between the surface of the substrate and the surface of the interposer.

4. The module of claim 1, wherein the substrate has a substrate thickness between the surface of the substrate and another surface of the substrate, and wherein the substrate optical waveguide is embedded within the substrate thickness.

5. The module of claim 1, wherein the interposer is electrically connected to the surface of the substrate.

6. The module of claim 5, wherein the main die is mechanically and electrically connected to the interposer, and wherein the main die is in electrical communication with the substrate via the interposer.

7. The module of claim 1, wherein the photonic IC is configured to be in optical communication with the interposer optical waveguide.

8. The module of claim 7, wherein the photonic IC is configured to be in electrical communication with the main die.

9. The module of claim 8, comprising a cooling system proximate the main die and the photonic IC, wherein the cooling system is configured to remove heat from the main die and the photonic IC.

10. The module of claim 1, wherein the module is deployed in a CPO package.

11. A method of manufacturing a module, the method comprising:
forming a substrate optical waveguide in a substrate;
forming an interposer optical waveguide through an interposer;
disposing a main die on a surface of the interposer;
disposing a photonic integrated circuit (IC) on the surface of the interposer; and
disposing the interposer on a surface of the substrate such that the photonic IC is in optical communication with the substrate optical waveguide via the interposer optical waveguide.

12. The method of claim 11, comprising performing a ball-grid-array reflow process to mechanically and electrically connect the substrate to a system printed circuit board.

13. The method of claim 11, comprising disposing a cooling system proximate the main die and the photonic IC.

14. The method of claim 11, comprising disposing an optical connector on the surface of the substrate such that the optical connector is in optical communication with the photonic IC via the substrate optical waveguide and the interposer optical waveguide.

15. A device, comprising:
a signal transmission region having a top sub-region;
one or more photonic integrated circuits (ICs) disposed in the top sub-region, wherein the one or more photonic ICs are in optical communication with the top sub-region; and
a main die disposed in the top sub-region proximate to and in substantially the same plane as the one or more photonic ICs, wherein the main die is in electrical communication with the one or more photonic ICs,
wherein the signal transmission region is configured to carry an optical signal to the signal transmission region through the signal transmission region to the top sub-region.

16. The device of claim 15, wherein the signal transmission region comprises:
a substrate region having a top substrate region; and
an interposer region disposed on the top substrate region.

17. The device of claim 16, wherein the substrate region comprises one or more substrate optical waveguides, and wherein the interposer region comprises one or more interposer optical waveguides.

18. The device of claim 17, wherein the interposer region is configured to optically align the one or more substrate optical waveguides with the one or more interposer optical waveguides.

19. The device of claim 17, wherein the one or more substrate optical waveguides are configured to convey optical signals.

20. The device of claim 16, wherein the top substrate region is configured to be in electrical communication with the interposer region.

21. The device of claim 15, wherein the signal transmission region is disposed on a system printed circuit board (PCB).

22. The device of claim 15, comprising a cooling system proximate the main die and the one or more photonic ICs, wherein the cooling system is configured to remove heat from the main die and the one or more photonic ICs.

23. The device of claim 15, wherein the device is deployed in a CPO package.

24. A method of manufacturing an electronic device, the method comprising:
providing a signal transmission region having a top sub-region;
disposing one or more photonic ICs in the top sub-region; and
disposing a main die in the top sub-region proximate to and in substantially the same plane as the one or more photonic ICs.

25. The method of claim 24, comprising:
providing a substrate region having a top substrate region in the signal transmission region; and
disposing an interposer region on the top substrate region.

26. The method of claim 25, comprising:
forming one or more substrate optical waveguides in the substrate region;
forming one or more interposer optical waveguides in the interposer region; and
optically aligning the one or more substrate optical waveguides with the one or more interposer optical waveguides.

27. The method of claim 26, comprising performing a ball-grid-array reflow process to mechanically and electrically connect the substrate region to a system printed circuit board.

28. The method of claim 27, comprising disposing a cooling system proximate the main die and the one or more photonic ICs.
